(19) United States
(12) Patent Application Publication
(10) Pub. No.: US 2023/0269552 A1
(43) Pub. Date: Aug. 24, 2023

(54) ELECTRONIC DEVICE, SYSTEM, METHOD AND COMPUTER PROGRAM

(71) Applicant: Sony Group Corporation, Tokyo (JP)

(72) Inventors: Michael ENENKL, Stuttgart (DE); Stefan UHLICH, Stuttgart (DE); Giorgio FABBRO, Stuttgart (DE)

(73) Assignee: Sony Group Corporation, Tokyo (JP)

(21) Appl. No.: 18/110,920

(22) Filed: Feb. 17, 2023

(30) Foreign Application Priority Data
Feb. 24, 2022 (EP) 22158656.3

(51) Int. Cl. H04S 7/00; G10L 19/008

(52) U.S. Cl. CPC H04S 7/30; G10L 19/008

(57) ABSTRACT

An electronic device comprising circuitry configured to receive an audio mixture signal and side information related to sources present in the audio mixture signal, perform audio source separation on the audio mixture to obtain separated sources, and generate respective virtual audio objects based on the separated sources and the side information.

### CROSS-REFERENCE TO RELATED APPLICATION

The present application claims priority to European Patent Application No. 22158656.3, filed Feb. 24, 2022, the entire contents of which are incorporated herein by reference.

### TECHNICAL FIELD

The present disclosure generally pertains to the field of audio processing, in particular to devices, systems, methods and computer programs for source separation and mixing.

### TECHNICAL BACKGROUND

There is a lot of audio content available, for example, in the form of compact disks (CD), tapes, audio data files which can be downloaded from the internet, but also in the form of sound tracks of videos, e.g. stored on a digital video disk or the like, etc. Typically, audio content is already mixed, e.g. for a mono or stereo setting without keeping original audio source signals from the original audio sources which have been used for production of the audio content. However, there exist situations or applications where a mixing of the audio content is envisaged.

Although there generally exist techniques for mixing audio content, it is generally desirable to improve devices and methods for mixing of audio content.

### SUMMARY

According to a first aspect, the disclosure provides an electronic device comprising circuitry configured to receive an audio mixture signal and side information related to sources present in the audio mixture signal, perform audio source separation on the audio mixture to obtain separated sources, and generate respective virtual audio objects based on the separated sources and the side information.

According to a second aspect, the disclosure provides an electronic device comprising circuitry configured to perform downmixing on a 3D audio signal to obtain an audio mixture signal, perform mixing parameters extraction on the 3D audio signal to obtain side information, and transmit the audio mixture signal and the side information related to sources present in the audio mixture signal.

According to a third aspect, the disclosure provides a system comprising a first electronic device according to claim 13 configured to perform downmixing on a 3D audio signal and to transmit an audio mixture signal and side information to a second electronic device according to claim 1, wherein the second electronic device is configured to generate respective virtual audio objects based on the audio mixture signal and the side information obtained from the first electronic device.

According to a fourth aspect, the disclosure provides a method comprising receiving an audio mixture signal and side information related to sources present in the audio mixture signal, performing audio source separation on the audio mixture to obtain separated sources, and generating respective virtual audio objects based on the separated sources and the side information.

According to a fifth aspect, the disclosure provides a computer program comprising program code causing a computer, when being carried out on a computer, to receive an audio mixture signal and side information related to sources present in the audio mixture signal, perform audio source separation on the audio mixture to obtain separated sources, and generate respective virtual audio objects based on the separated sources and the side information.

Further aspects are set forth in the dependent claims, the following description and the drawings.

### BRIEF DESCRIPTION OF THE DRAWINGS

Embodiments are explained by way of example with respect to the accompanying drawings, in which:

FIG. 1 schematically shows a general approach of audio upmixing/remixing by means of blind source separation (BSS), such as music source separation (MSS);

FIG. 2 schematically shows an embodiment of a process of downmixing and remixing/upmixing using audio source separation;

FIG. 3 schematically shows in more detail an embodiment of the sender described in FIG. 2;

FIG. 4 shows an embodiment of metadata and audio data comprised in a 3D audio signal;

FIG. 5 schematically shows in more detail an embodiment of the receiver described in FIG. 2;

FIG. 6 schematically shows side information comprising respective rendering information for each of the separated sources of a 3D audio signal. As described with regard to FIG. 3 above, source separation is performed on the 3D audio signal to obtain separated sources;

FIG. 7 shows a matching process of a spectrogram comprised in the side information with a spectrogram of a separated source;

FIG. 8 provides a schematic diagram of a system applying digitalized monopole synthesis algorithm;

FIG. 9 schematically shows an embodiment of audio input signal enhancement, wherein the audio signal being input to for downmixing, as described in FIG. 2, is an enhanced audio signal;

FIG. 10 shows a histogram of two instruments of an audio signal, wherein the two instruments have a spectral overlap;

FIG. 11 shows a flow diagram visualizing a method for performing downmixing and remixing/upmixing of an audio signal using audio source separation; and

FIG. 12 schematically describes an embodiment of an electronic device that can implement the processes of downmixing and remixing/upmixing using audio source separation;

### DETAILED DESCRIPTION OF EMBODIMENTS

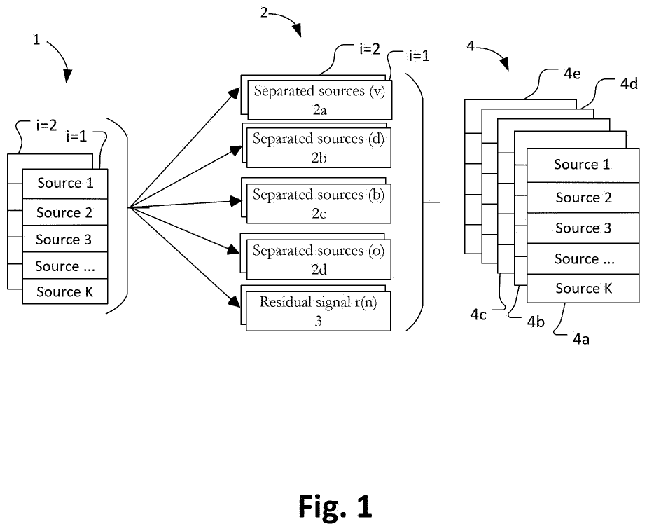

Before a detailed description of the embodiments under reference of FIGS. 1 to 12, general explanations are made.

Generally, audio files (music) contain a mixture of several sources or audio objects. To transmit the original sources, e.g. audio objects, it would require a higher bandwidth than the stereo or monaural mix.

Due to the shift in playback systems to 3D audio it would be good to obtain the audio objects with no increase of the utilized transmission bandwidth (e.g. audio streaming services) while maintaining a defined playback quality level.

Blind source separation (BSS), also known as blind signal separation, is the separation of a set of source signals from a set of mixed signals. One application for Blind source separation (BSS), is the separation of music into the individual instrument tracks such that an upmixing or remixing of the original content is possible.

In the following, the terms remixing, upmixing, and downmixing can refer to the overall process of generating output audio content based on separated audio source signals originating from mixed input audio content, while the term “mixing” can refer to the mixing of the separated audio source signals. Hence the “mixing” of the separated audio source signals can result in a “remixing”, “upmixing” or “downmixing” of the mixed audio sources of the input audio content.

The embodiments described below provide an electronic device comprising circuitry configured to receive an audio mixture signal and side information related to sources present in the audio mixture signal, perform audio source separation on the audio mixture to obtain separated sources, and generate respective virtual audio objects based on the separated sources and the side information.

The electronic device may for example be any music or movie reproduction device such as smartphones, Headphones, a TV sets, a Blu-ray player or the like.

The circuitry of the electronic device may include a processor, may for example be CPU, a memory (RAM, ROM or the like), a memory and/or storage, interfaces, etc. Circuitry may comprise or may be connected with input means (mouse, keyboard, camera, etc.), output means (display (e.g. liquid crystal, (organic) light emitting diode, etc.)), loudspeakers, etc., a (wireless) interface, etc., as it is generally known for electronic devices (computers, smartphones, etc.). Moreover, circuitry may comprise or may be connected with sensors for sensing still images or video image data (image sensor, camera sensor, video sensor, etc.), for sensing environmental parameters (e.g. radar, humidity, light, temperature), etc.

The audio mixture signal may be a stereo, a monaural or even a multichannel signal.

The side information related to sources present in the audio mixture signal may comprise metainformation, e.g. rendering information. The side information related to sources present in the audio mixture signal may comprise audio data, e.g. a spectrogram of a source. The sources present in the audio mixture signal may be any sound source present in an audio signal, such as vocals, drums, bass, guitar, etc.

In audio source separation, an input signal comprising a number of sources (e.g. instruments, voices, or the like) is decomposed into separations. Audio source separation may be unsupervised (called “blind source separation”, BSS) or partly supervised. “Blind” means that the blind source separation does not necessarily have information about the original sources. For example, it may not necessarily know how many sources the original signal contained, or which sound information of the input signal belong to which original source. The aim of blind source separation is to decompose the original signal separations without knowing the separations before. A blind source separation unit may use any of the blind source separation techniques known to the skilled person. In (blind) source separation, source signals may be searched that are minimally correlated or maximally independent in a probabilistic or information-theoretic sense or based on a non-negative matrix factorization structural constraint on the audio source signals can be found. Methods for performing (blind) source separation are known to the skilled person and are based on, for example, principal components analysis, singular value decomposition, (in)dependent component analysis, non-negative matrix factorization, artificial neural networks, etc.

Although, some embodiments use blind source separation for generating the separated audio source signals, the present disclosure is not limited to embodiments where no further information is used for the separation of the audio source signals, but in some embodiments, further information is used for generation of separated audio source signals. Such further information can be, for example, ins formation about the mixing process, information about the type of audio sources included in the input audio content, information about a spatial position of audio sources included in the input audio content, etc.

The electronic device may receive the audio mixture signal and the side information related to sources present in the audio mixture signal from another electronic device, such as a sender or the like. The sender may be an audio distribution device or the like.

A virtual audio object may be a virtual sound source. The virtual sound source may, for example, be a sound field which gives the impression that a sound source is located in a predefined space. For example, the use of virtual sound sources may allow the generation of spatially limited audio signal. In particular, generating virtual sound sources may be considered as a form of generating virtual speakers throughout the three-dimensional space, including behind, above, or below the listener.

Virtual audio objects generation may be performed based on a 3D audio rendering operation, which may for example be based on Wavefield synthesis. Wavefield synthesis techniques may be used to generate a sound field that gives the impression that an audio point source is located inside a predefined space. Such an impression can, for example, be achieved by using a Wavefield synthesis approach that drives a loudspeaker array such that the impression of a virtual sound source is generated.

The 3D audio rendering operation may be based on monopole synthesis. Monopole synthesis techniques may be used to generate a sound field that gives the impression that an audio point source is located inside a predefined space. Such an impression can, for example, be achieved by using a monopole synthesis is approach that drives a loudspeaker array such that the impression of a virtual sound source is generated.

The audio source separation, e.g. blind source separation may reconstruct the original audio objects from the mix. These new objects may be remixed in the 3D space on a playback device. The 3D mixing parameter may also be transmitted highly compressed as binary data (x,y,z coordinates, gain, spread) or even be inaudibly hidden in the audio data. In this way less bandwidth may be used and also less storage space on the devices.

In this manner, it may be possible to transmit multi-channel audio such that it does not require more bandwidth and can be played on legacy receivers as “normal audio”, e.g., on two loudspeakers as the mixture is stereo audio, while allowing, using source separation, to be played as 3D audio.

The side information may comprise respective rendering information for each of the separated sources. The rendering information may be 3D mixing parameters obtained in the mixing stage (sender) when producing a 3D audio signal. The rendering information may be spatial information, e.g. X, Y, Z coordinates, gain parameters, spread parameter and the like.

The circuitry may be configured to generate a virtual audio object by associating a separated source to its respective rendering information. For example, the renderer of the virtual audio object gets an ID number for each object and the rendering information contains this ID number, too. Thus, both may be aligned. The association of the virtual audio object to its respective rendering information may be performed by matching side information related to sources present in the audio mixture signal to separated sources of the audio mixture. That is, the association of the virtual audio object to its respective rendering information may be performed by matching a spectrogram of a source present in the audio mixture, the spectrogram is comprised in the side information, to a spectrogram of a separated source obtained by performing (audio) source separation to the audio mixture.

In some embodiments, the side information may be received as binary data.

In some embodiments, the side information may be received as inaudible data included in the audio mixture signal.

In some embodiments, the side information may comprise information indicating that a specific source is present in the audio mixture signal. The specific source may be any instrument present in the audio mixture signal, for example, vocals, bass, drums, guitar, and the like. The information indicating that a specific source is present in the audio mixture signal may be information stemming either from a metadata file or from an instrument detector that is run on the sender side.

In some embodiments, the side information may comprise information indicating spatial positioning parameters for a specific source. The spatial positioning parameters may comprise information about the location of a specific source present in the audio mixture signal, i.e., where the specific source may be placed in the 3D space by the playback device. The spatial mixing parameters may be three-dimensional, 3D, audio mixing parameters. The 3D mixing parameter may be transmitted highly compressed as binary data (x,y,z coordinates, gain, spread) or even be inaudibly hidden in the audio data.

In some embodiments, the side information may comprise information indicating a network architecture to be used for source separation.

In some embodiments, the side information may comprise information indicating a separator model among a plurality of stored separator models to be used for audio source separation. The information indicating a separator model may be information about which separator model may be used for audio source separation if the electronic device (e.g. receiver) has several models from which the electronic device (e.g. receiver) could choose, e.g., different weight sets which are optimized for a music genre. For example, each instrument, i.e. for each specific source present in the audio mixture signal, is associated with at least one network, model. Depending on the specific sources that are present in the audio mixture signal, the electronic device is able to choose the most suitable network, model to perform audio source separation. In this manner, the audio source separation provides a optimized result.

The circuitry may be further configured to render the generated virtual audio object by means of a playback device.

In some embodiments, the audio mixture signal may be a stereo signal.

In some embodiments, the audio mixture signal may be a monaural signal.

The embodiments described below also provide an electronic device comprising circuitry configured to perform downmixing on a 3D audio signal to obtain an audio mixture signal, perform mixing parameters extraction on the 3D audio signal to obtain side information, and transmit the audio mixture signal and the side information related to sources present in the audio mixture signal. The side information may be explicitly transmitted, e.g., additional bits in the WAV file header, or may be embedded into the audio waveform, e.g., into the least significant bits of a PCM signal. The side information may be embedded into the audio stream, e.g., the stereo audio signal.

In this manner, may the number of channels for multi-channel or object-based audio data transmission may be reduced. The quality level of the transmission may be dynamically adjusted. The spectral mixing approach may possibly also be used in classical music production. The transmitted audio may be re-mixed in the 3D space using highly compressed binary mixing data.

The side information may comprise rendering information related to the 3D audio signal.

In some embodiments, the circuitry may be configured to perform spectral decoupling on the 3D audio signal to obtain a decoupled spectral of the 3D audio signal. For example, a mixing process may be used, which may not be optimized for stereo playback, but for minimized artefacts during decoding, while maintaining a decent quality as a classical stereo mix. By spectrally decoupling the different instruments, i.e. the specific sources, the audio source separation algorithm may perform in an excellent quality.

In some embodiments, the circuitry may be configured to perform spectral overlap comparison of the decoupled spectral of the 3D audio signal to obtain an enhanced 3D audio signal. For example, comparison of the spectral overlap may be performed. If there is no overlap of e.g. two specific sources, the audio mixture may be simply transmitted to the receiver. Otherwise, the specific sources may be spectrally weaved together, e.g., with an odd and even FFT bin usage for each instrument. Or if there is spectral overlay, more channels or objects may be transmitted, so that to optimize the quality bandwidth ratio dynamically. As the spectral overlap may also exist in the audio mixing task, this spectral interleaving proposal may possibly also have a benefit.

The embodiments described below also provide a system comprising a first electronic device according to claim 13 configured to perform downmixing on a 3D audio signal and to transmit an audio mixture signal and side information to a second electronic device according to claim 1, wherein the second electronic device is configured to generate respective virtual audio objects based on the audio mixture signal and the side information obtained from the first electronic device.

The system may reduce the number of channels for multi-channel or object-based audio data transmission. The quality level of the transmission may be dynamically adjusted. The spectral mixing approach may possibly also be used in classical music production. The transmitted audio may be remixed in the 3D space using highly compressed binary mixing data. Also there may be compatibility to a normal stereo audio production.

In this manner, it may be possible to transmit multi-channel audio such that it does not require more bandwidth and can be played on legacy receivers as “normal audio”, e.g., on two loudspeakers as the mixture is stereo audio, while allowing, using source separation, to be played as 3D audio.

The embodiments described below also provide a method comprising receiving an audio mixture signal and side information related to sources present in the audio mixture signal, performing audio source separation on the audio mixture to obtain separated sources, and generating respective virtual audio objects based on the separated sources and the side information.

The embodiments described below also provide a computer program comprising program code causing a computer to, when being carried out on a computer, receive an audio mixture signal and side information related to sources present in the audio mixture signal, perform audio source separation on the audio mixture to obtain separated sources, and generate respective virtual audio objects based on the separated sources and the side information.

Embodiments are now described by reference to the drawings.

### Audio Mixing by Means of Audio Source Separation

FIG. 1 schematically shows a general approach of audio upmixing/remixing by means of blind source separation (BSS), such as music source separation (MSS).

First, source separation (also called “demixing”) is performed which decomposes a source audio signal 1 comprising multiple channels I and audio from multiple audio sources Source 1, Source 2, . . . , Source K (e.g. instruments, voice, etc.) into “separations”, here into source estimates 2a-2d for each channel i, wherein K is an integer number and denotes the number of audio sources. In the embodiment here, the source audio signal 1 is a stereo signal having two channels i=1 and i=2. As the separation of the audio source signal may be imperfect, for example, due to the mixing of the audio sources, a residual signal 3 (r(n)) is generated in addition to the separated audio source signals 2a-2d. The residual signal may for example represent a difference between the input audio content and the sum of all separated audio source signals. The audio signal emitted by each audio source is represented in the input audio content 1 by its respective recorded sound waves. For input audio content having more than one audio channel, such as stereo or surround sound input audio content, also a spatial information for the audio sources is typically included or represented by the input audio content, e.g. by the proportion of the audio source signal included in the different audio channels. The separation of the input audio content 1 into separated audio source signals 2a-2d and a residual 3 is performed on the basis of blind source separation or other techniques which are able to separate audio sources.

In a second step, the separations 2a-2d and the possible residual 3 are remixed and rendered to a new loudspeaker signal 4, here a signal comprising five channels 4a-4e, namely a 5.0 channel system. On the basis of the separated audio source signals and the residual signal, an output audio content is generated by mixing the separated audio source signals and the residual signal on the basis of spatial information. The output audio content is exemplary illustrated and denoted with reference number 4 in FIG. 1.

In the following, the number of audio channels of the input audio content is referred to as Mᵢₙ and the number of audio channels of the output audio content is referred to as Mₒᵤₜ. As the input audio content 1 in the example of FIG. 1 has two channels i=1 and i=2 and the output audio content 4 in the example of FIG. 1 has five channels 4a-4e, Mᵢₙ=2 and Mₒᵤₜ=5. The approach in FIG. 1 is generally referred to as remixing, and in particular as upmixing if Mᵢₙ<Mₒᵤₜ. In the example of the FIG. 1 the number of audio channels Mᵢₙ=2 of the input audio content 1 is smaller than the number of audio channels Mₒᵤₜ=5 of the output audio content 4, which is, thus, an upmixing from the stereo input audio content 1 to 5.0 surround sound output audio content 4.

### Audio Rendering by Means of Audio Source Separation

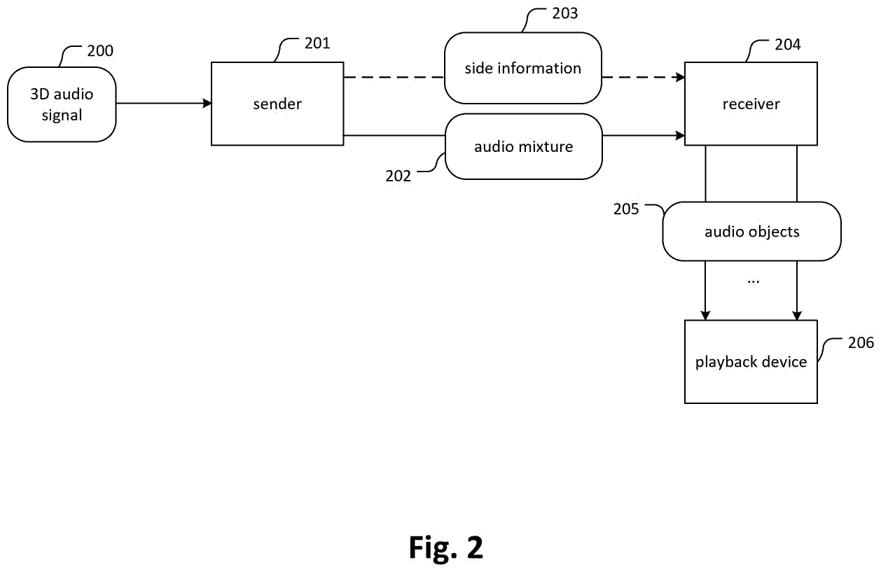

FIG. 2 schematically shows an embodiment of a process of downmixing and remixing/upmixing using audio source separation. The process is performed on a system comprising a sender and a receiver, wherein the downmixing is performed on the sender side and the remixing/upmixing using audio source separation is performed on the receiver side.

A three-dimensional, 3D, audio signal 200 (see audio input signal 1 in FIG. 1) containing multiple sources (see 1, 2, . . . , K in FIG. 1), with, for example, multiple channels (e.g., Mᵢₙ=3 or more) e.g. a piece of music, is input to a sender 201 and processed to obtain an audio mixture signal 202, e.g. a stereo audio signal, and side information 203, e.g. 3D mixing parameters. The audio mixture signal 202 and the side information 203 are processed by a receiver 204 to obtain virtual audio objects 205, e.g., monopoles. A playback device 206 renders the virtual audio objects 205.

In the embodiment of FIG. 2, the sender 201 may compress the three-dimensional, 3D, audio signal 200 to obtain the audio mixture signal 202, which may be a stereo signal or a monaural signal. In addition, the sender 201 may compress the 3D audio signal 200 to obtain side information, for example, 3D mixing parameters. The playback device 206 may be any device that can render the virtual audio objects, for example, the playback device 206 may be a smartphone, a laptop, a computer or any electronic device having a loudspeaker array.

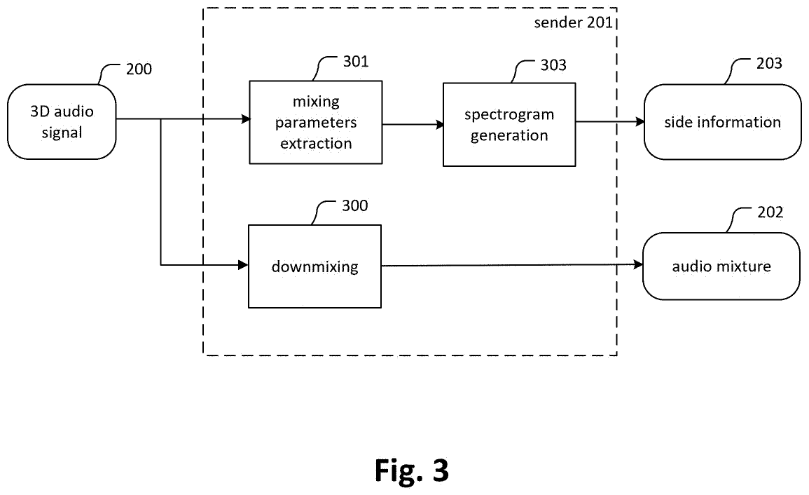

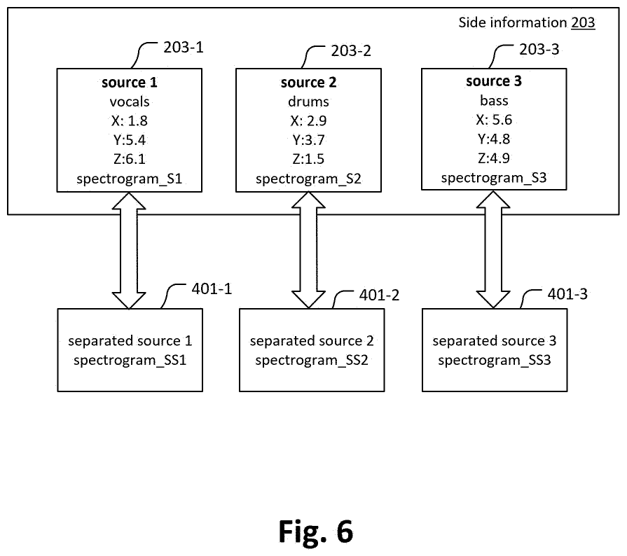

The sender 201 may perform a process of downmixing and a process of mixing parameters extraction as described in the embodiment of FIG. 3 in more detail. The receiver 204 may perform a process of audio source separation, e.g. blind source separation, and a process of audio object generation as described in the embodiment of FIG. 6 in more detail.

It should be noted that with the above-described process of FIG. 2, it may be possible to transmit multi-channel audio such that it does not require more bandwidth and may be played on legacy receivers as “normal audio”, e.g., on two loudspeakers as the mixture is stereo audio, while allowing, using blind source separation, to be played as 3D audio. The above-described process of FIG. 2 may utilize less bandwidth but also less storage space on the playback devices. In this manner, the number of channels for multi-channel or object-based audio data transmission is reduced and the quality level of the transmission may be dynamically adjusted.

### Audio Downmixing

FIG. 3 schematically shows in more detail an embodiment of the sender described in FIG. 2. The three-dimensional, 3D, audio signal 200 containing multiple sources is input to the sender 201 and processed to obtain an audio mixture signal 202 and side information 203, as described in FIG. 2 above. The three-dimensional, 3D, audio signal 200 contains a mixture of several audio sources or multiple audio objects. The three-dimensional, 3D, audio signal 200 has a bandwidth higher than a bandwidth of a stereo audio signal or a monaural audio signal.

A downmixing 300 compresses the three-dimensional, 3D, audio signal 200 to obtain an audio mixture signal 202, e.g., a stereo audio signal. A mixing parameters extraction 301 and a spectrogram generation 303 is performed on the three-dimensional, 3D, audio signal 200 to obtain side information 203, e.g. 3D mixing parameters. The 3D mixing parameters may be transmitted to a receiver (see 204 in FIG. 2) highly compressed as binary data comprising X, Y, Z coordinates, gain, spread, and the like, without limiting the present embodiment in that regard. The 3D mixing parameters may be inaudibly hidden in the audio mixture signal 202, i.e. audio data. The side information 203 may comprise metadata, e.g. meta information and audio data.

From a data coding point of view, audio objects consist of audio data which is comprised in the audio object stream as an audio bitstream plus associated metadata (object position, gain, etc.). The associated metadata related to audio objects for example comprises positioning information related to the audio objects, i.e. information describing where an audio object should be position in the 3D audio scene. This positioning information may for example be expressed as 3D coordinates (x, y, z) of the audio object (see 205 in FIG. 2). In the embodiment of FIG. 3, the mixing parameters extraction 301 obtains the coordinates (x, y, z) of the audio objects within the audio object stream. These extracted coordinates (x, y, z) of the audio objects represent the field of listening in which the driver is immersed.

Audio objects streams are typically described by a structure of a metadata model that allows the format and content of audio files to be reliably described. In the following embodiment, it is described as an example of a metadata model, the Audio Definition Model (ADM) specified in ITU Recommendation ITU-R BS.2076-1 Audio Definition Model. This Audio Definition Model specifies how XML metadata can be generated to provide the definitions of audio objects.

As described in ITU-R BS.2076-1, an audio object stream is described by an audio stream format, such as audioChannelFormat including a typeDefinition attribute, which is used to define what the type of a channel is. ITU-R BS.2076-1 defines five types for channels, namely DirectSpeakers, Matrix, Objects, HOA, and Binaural, as described on Table 10 of ITU-R BS.2076-1, which we reproduce below:

TABLE 10
typeDefinitions

| typeDefinition | typeLabel | Description |
|---|---|---|
| DirectSpeakers | 0001 | For channel-based audio, where each, |
| | | channel feeds a speaker directly |
| Matrix | 0002 | For channel-based audio where channels |
| | | are matrixed together, such as Mid-Side, |
| | | Lt/Rt |
| Objects | 0003 | For object-based audio where channels |
| | | represent audio objects (or parts of |
| | | objects) and so include positional |
| | | information |
| HOA | 0004 | For scene-based audio where Ambisonics |
| | | and HOA are used |
| Binaural | 0005 | For binaural audio, where playback is |
| | | over headphones |

In this embodiment, it is focused on type definition “Objects” which are described in section § 5.4.3.3 of ITU-R BS.2076-1. In this section of ITU-R BS.2076-1 it is described that object-based audio comprises parameters that describe a position of the audio object (which may change dynamically), as well as the object's size, and whether it is a diffuse or coherent sound. The position and object size parameters definitions depend upon the coordinate system used and they are individually described in Tables 14, 15 and 16, of the ITU Recommendation ITU-R BS.2076-1 Audio Definition Model.

The position of the audio object is described in a sub-element “position” of the audioBlockFormat for “Objects”. ITU-R BS.2076-1 provides two alternative ways of describing the position of an audio object, namely in the Polar coordinate system, and, alternatively, in the Cartesian coordinate system. A coordinate sub-element “cartesian” is defined in Table 16 of ITU-R BS.2076-1 with value 0 or 1. This coordinate parameter specifies which of these types of coordinate systems is used.

TABLE 16
audioBlockFormat sub-elements for Objects

| Sub-element | Attribute | Description | Units | Example | Quantity | Default |
|---|---|---|---|---|---|---|
| cartesian | | Specifies coordinate | 1/0 flag | 1 | 0 or 1 | 0 |
| | | system, if the flag is set to | | | | |
| | | 1 the Cartesian coordinate | | | | |
| | | system is used, otherwise | | | | |
| | | spherical coordinates are | | | | |
| | | used. | | | | |
| gain | | Apply a gain to the audio | linear gain value | 0.5 | 0 or 1 | 1.0 |
| | | in the object | | | | |
| diffuse | | Describes the diffuseness | 0.0 to 1.0 | 0.5 | 0 or 1 | 0 |
| | | of an audioObject | | | | |
| | | (if it is diffuse or direct | | | | |
| | | sound) | | | | |

If the “cartesian” parameter is zero (which is the default), a Polar Coordinate system is used. Thus, the primary coordinate system defined in ITU-R BS.2076-1 is the Polar coordinate system, which uses azimuth, elevation and distance parameters as defined in Table 14 of ITU-R BS.2076-1, which is reproduced below:

TABLE 14
audioBlockFormat sub-elements for Objects (polar)

| Sub-element | Attribute | Description | Units | Example | Quantity | Default |
|---|---|---|---|---|---|---|
| position | coordinate = | azimuth “theta” of | Degrees | −22.5 | 1 | |
| | “azimuth” | sound location | (−180 ≤ theta ≤ 180) | | | |
| position | coordinate = | elevation “phi” of | Degrees | 5.0 | 1 | |
| | “elevation” | sound location | (−90 ≤ phi ≤ 90) | | | |
| position | coordinate = | distance “ [symbol] ” | abs( [symbol] ) | 0.9 | 0 or 1 | 1.0 |
| | “distance” | from origin | | | | |
| width | | horizontal extent | Degress | 45 | 0 or 1 | 0.0 |
| height | | vertical extent | Degrees | 20 | 0 or 1 | 0.0 |
| depth | | distance extent | Ratio | 0.2 | 0 or 1 | 0.0 |

[symbol]

indicates data missing or illegible when filed

Alternatively, it is possible to specify the position of an audio object in the Cartesian coordinate system. For a Cartesian coordinate system, the position values (X, Y and Z) and the size values are normalized to a cube:

TABLE 15
audioBlockFormat sub-elements for Objects (Cartesian)

| Sub-element | Attribute | Description | Units | Example | Quantity | Default |
|---|---|---|---|---|---|---|
| position | coordinate = “X” | left/right dimension | Normalized Units | −0.2 | 1 | |
| position | coordinate = “Y” | back/front dimension | Normalized Units | 0.1 | 1 | |
| position | coordinate = “Z” | bottom/top dimension | Normalized Units | −0.5 | 0 or 1 | 0.0 |
| width | | X-width | Normalized Units | 0.03 | 0 or 1 | 0.0 |
| depth | | Y-width | Normalized Units | 0.05 | 0 or 1 | 0.0 |
| height | | Z-width | Normalized Units | 0.07 | 0 or 1 | 0.0 |

A sample XML code which illustrates the position coordinates (x,y,z) is given in section 5.4.3.3.1 of ITU-R BS.2076-1 by

```
<audioBlockFormat ...>
  <position coordinate=“azimuth”>−22.5</position>
  <position coordinate=“elevation”>−5.0</position>
  <position coordinate=“distance”>−0.9</position>
  <depth>0.2</depth>
</audioBlockFormat>
```

Based on the description of ITU-R BS.2076-1 audio definition model described above in more detail, the coordinate extraction process described with regard to FIG. 3 above (see 301 in FIG. 3) may for example be realized by reading these coordinate attributes (x, y, z) or (azimuth, elevation, distance) from the position sub-element of an audioBlockFormat definition included in the metadata of the audio object stream.

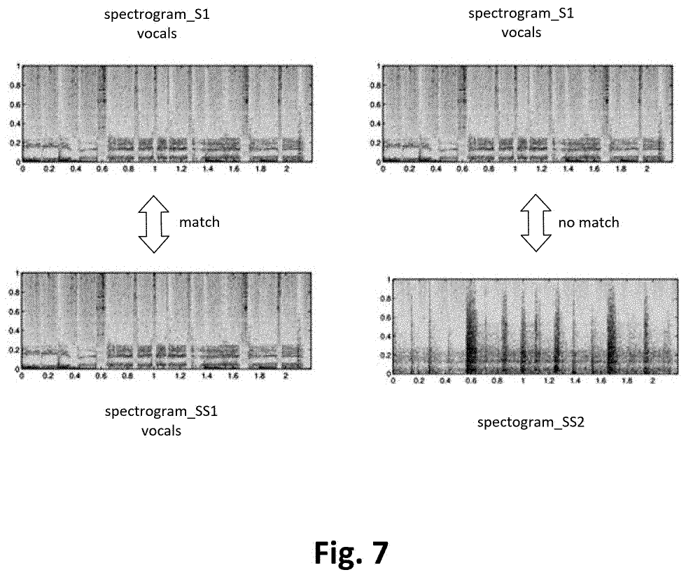

An example of the metadata of an audio block of an audio object is given in TABLE 16 and in FIG. 7 in section 5.4.3.3 of ITU-R BS.2076-1. This example of the metadata contains also the extracted parameters mentioned above.

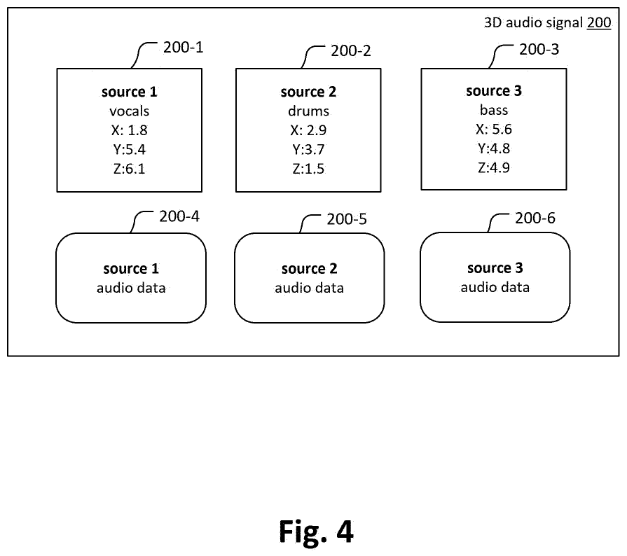

In the embodiment of FIG. 3, the extracted 3D mixing parameters are transmitted, e.g. to the receiver 204 of FIG. 4, highly compressed as binary data. The extracted 3D mixing parameter may also be transmitted e.g. to downmixing 300 and be used for downmix purposes. Downmixing 300 compresses the three-dimensional, 3D, audio signal 200 to obtain e.g., a stereo audio signal. This downmixing may also be performed with monopole synthesis where there are two loudspeakers only and which correspond to left/right channel.

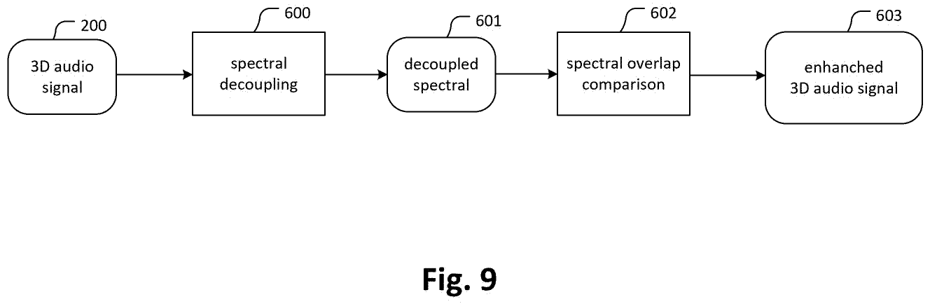

In the embodiment of FIG. 3, the downmixing 300 may be implemented as described in FIG. 9 below. In the embodiment of FIG. 3, the side information 203 extracted by the mixing parameters extraction 301 may be information about which instruments, i.e. audio sources, are present in the audio signal 200. The side information 203 may comprise respective rendering information for each of the audio sources of the three-dimensional, 3D, audio signal 200. This information stems either from a metadata file or from an instrument detector which may be implemented on the sender 201. The side information 203 may be information about which separator model can be used for audio source separation if for example, the receiver (see 204 in FIG. 2) could choose between several models, e.g., different weight sets which are optimized for a music genre. Moreover, the side information 203 may be information about the optimal network architecture that can be used for audio source separation e.g., if there is a “once-for-all” supernet trained as described by Cai, Han, et al. in the published paper “Once-for-all: Train one network and specialize it for efficient deployment” (arXiv preprint arXiv:1908.09791 (2019)). Furthermore, the side information 203 may contain information about the location of the audio sources of the audio signal 200, i.e., where these audio sources can be placed in the 3D space by a playback device (see 206 in FIG. 2).

It should be noted that the side information 203 may be either explicitly transmitted, e.g., additional bits in the WAV file header or may be embedded into the audio waveform, e.g., into the least significant bits of a PCM signal.

The side information 203 extracted by the mixing parameters extraction 301 can be used for rendering, to suitable positions in the 3D space, the audio mixture signal 202 by a playback device (see 206 in FIG. 2) e.g. by a loudspeaker array of the playback device so that the final output sound may be optimized.

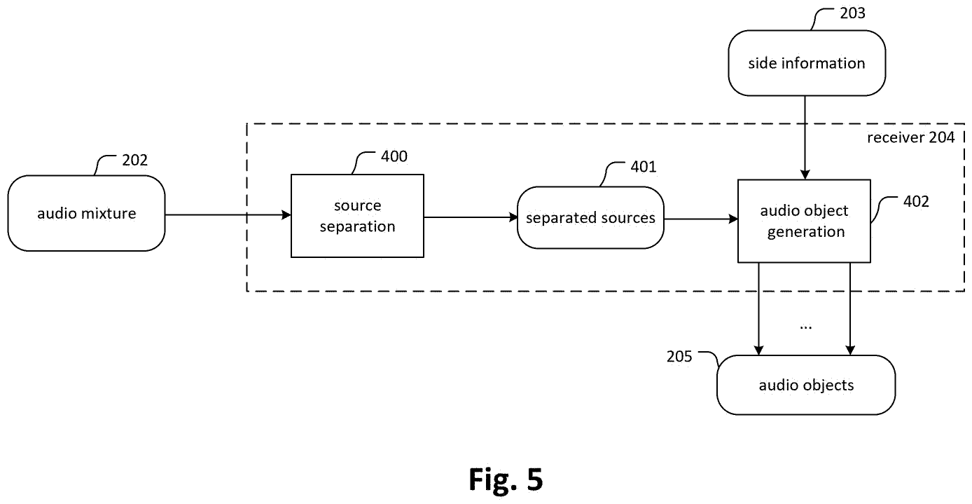

FIG. 4 shows an embodiment of metadata and audio data comprised in a 3D audio signal. The 3D audio signal 200 comprises metadata 200-1, 200-2, 200-3 and audio data 200-4, 200-5, 200-6. The metadata 200-1, 200-2, 200-3 includes meta information indicating what specific sources are present in the 3D audio signal, and rendering information, namely spatial parameters, etc. Here, the audio data 200-4, 200-5, 200-6 comprises for example, the spectrogram of each specific source which is present in the 3D audio signal 200. The spectrogram of each specific source which is present in the 3D audio signal 200 is a fingerprint which may be used to identify a separated source of the audio signal, as described in FIGS. 5 and 6 in more detail. The spectrogram of each specific source may be transmitted with a very low resolution together with the audio mixture.

In the embodiment of FIG. 4, the 3D audio signal 200 comprises three sources, namely source 1, source 2 and source 3. Source 1 is vocals, source 2 is drums and source 3 is bass. The first source 200-1 is vocals and is related to rendering information indicating as spatial parameters the coordinates X: 1.8, Y: 5.4, Z: 6.1. The second source 200-2 is drums and is related to rendering information indicating as spatial parameters the coordinates X: 2.9, Y: 3.7, Z: 1.5. The third source 200-3 is bass and is related to rendering information indicating as spatial parameters the coordinates X: 5.6, Y: 4.8, Z: 4.9.

The metadata 200-1, 200-2, 200-3 and audio data 200-4, 200-5, 200-6 may be extracted from the 3D audio signal 200 by performing mixing parameters extraction (see 301) as described in FIG. 3 above.

### Audio Object Generation Based on Separated Sources

FIG. 5 schematically shows in more detail an embodiment of the receiver described in FIG. 2. An audio mixture signal 202, e.g., a stereo audio, is processed by the receiver 204 based on side information 203 e.g. 3D mixing parameters, related to the audio mixture signal 202. The audio mixture signal 202 is obtained by performing downmixing (see 300 in FIG. 3) on an audio signal (see 200 in FIGS. 2 and 3), as described in FIG. 2 above. The side information 203, e.g. 3D mixing parameters, is obtained by performing mixing parameters extraction (see 301 in FIG. 3) on the audio signal (see 200 in FIGS. 2 and 3), as described in FIG. 2 above.

A source separation 400 is performed on the audio mixture signal 202 to obtain separated sources 401. An audio object generation 402 is performed based on the separated sources 401 and based on side information 203, e.g. 3D mixing parameters, related to the audio mixture signal 202, to obtain virtual audio objects 205, e.g. monopoles.

In the embodiment of FIG. 5, the source separation 400 is an audio source separation, e.g. blind source separation, and is performed as described in more detail in FIG. 1 above. The audio mixture signal 202 may be a stereo signal or a monaural audio signal. By using the normal stereo or even monaural audio signal transmission, the receiver 204 may reconstruct the original audio objects or audio sources (instruments) from the mix. These new objects then may be remixed in the 3D space on a playback device. In this manner, as described in FIG. 2, the generated audio objects 205 are output in the 3D space by a playback device e.g. having a loudspeaker array.

In the embodiment of FIG. 5, the side information 203 includes for example, 3D mixing parameters. The side information 203 may also include information about the optimal settings for performing source separation 400 (separator networks). In this manner the performance of the source separation 400 (separator networks) may be optimized in a given use case. The audio object generation 402 may be implemented as described in FIG. 9 below.

In the embodiment of FIG. 5, the side information 203 may comprise respective rendering information for each of the separated sources 401, as described in FIG. 6. The virtual audio object 205 may be generated by associating a separated source among the separated sources 401 to its respective rendering information, as described in FIG. 7. The renderer of the virtual audio object 205 gets an ID number for each separated source among the separated sources 401 and the rendering information contains this ID number, too. In this manner, both can be aligned.

### Separated Source Association to its Respective Rendering Information

FIG. 6 schematically shows side information comprising respective rendering information for each of the separated sources of a 3D audio signal. As described with regard to FIG. 3 above, source separation is performed on the 3D audio signal to obtain separated sources.

Here the 3D audio signal comprises three specific sources, namely source 1, source 2 and source 3. Source 1 is vocals, source 2 is drums and source 3 is bass. The side information 203 comprises respective rendering information X, Y, Z related to the specific sources 203-1, 203-2, 203-3, the respective rendering information X, Y, Z is associated to each one of the three separated sources 401-1, 401-2, 401-3 of the 3D audio signal.

The first meta information related to the first specific source, source 1, comprises information indicating what instrument is the first specific source, here vocals, rendering information indicating the X, Y, Z coordinates of the first specific source, here X: 1.8, Y: 5.4, Z: 6.1, and information indicating the spectrogram of the first specific source, spectrogram_S1. The second meta information related to the second specific source, source 2, comprises information indicating what instrument is the second specific source, here drums, rendering information indicating the X, Y, Z coordinates of the second separated source, here X: 2.9, Y: 3.7, Z: 1.5, and information indicating the spectrogram of the second specific source, spectrogram_S2. The meta information related to the third specific source, source 3, comprises information indicating what instrument is the third specific source, here bass, rendering information indicating the X, Y, Z coordinates of the third specific source, here X: 5.6, Y: 4.8, Z: 4.9, and information indicating the spectrogram of the third specific source, spectrogram_S3.

Each one of the first, second and third meta information comprised in the side information 203 and related to a respective specific source is associated with a respective separated source 401-1, 401-2, 401-3 obtained by performing source separation on a mixture signal of the 3D audio signal as described herein. Each separated source is represented by a respective spectrogram, namely the first separated source 401-1 has a spectrogram_SS1, the second separated source 401-2 has a spectrogram_SS2, and the third separated source 401-3 has a spectrogram_SS3.

Each separated source 401-1, 401-2, 401-3 is matched and thus associated to its respective meta information and rendering information X, Y, Z, as described in FIG. 7.

In the embodiment of FIG. 6, the meta information may provide information about the frequency space of each specific source in the audio signal. The rendering information may be 3D mixing parameters obtained in the mixing stage (sender) when producing a 3D audio signal.

FIG. 7 shows a matching process of a spectrogram comprised in the side information with a spectrogram of a separated source. The matching process is performed by comparing the spectrogram, i.e. frequency spectrum, comprised in each rendering information of the side information to the spectrogram, i.e. frequency spectrum, of each separated source. Here, on the upper left and right part of FIG. 7, a spectrogram, spectrogram_S1, which is the vocals spectrogram, is comprised in the first rendering information of the side information (see 203). On the lower left part of FIG. 7, a spectrogram, spectrogram_SS1, is the spectrogram of a first separated source, here vocals. On the lower right part of FIG. 7, a spectrogram, spectrogram_SS1, is the spectrogram of a second separated source.

A matching process is performed between each spectrogram of a source comprised in the side information and the spectrogram of each separated source comprised in the audio mixture signal. On the left part of FIG. 7, the spectrogram, spectrogram_S1, of a source, here vocals, comprised in the side information matches the spectrogram, spectrogram_SS1, and thus, the first separated source, here vocals, is associated to its respective rendering information, here first rendering information 203-1. On right part of FIG. 7, the spectrogram, spectrogram_S1, of a source, here vocals, comprised in the side information, does not match to the spectrogram, spectrogram_SS2, and thus, the separated source, having spectrogram_SS2, is not associated to the rendering information comprising the spectrogram_S1, namely the spectrogram of the vocals. By performing the matching process each separated source is associated to its respective rendering information.

In the embodiment of FIG. 7, process each separated source is associated to its respective rendering information by performing e.g. a spectrogram comparison. For example, by quantifying the difference between the two spectrograms. The difference between the two spectrograms may be with respect to a range of frequencies. The average power at a particular frequency may be calculated based on the power spectral density (PSD) obtained using e.g. a “spectrogram” function.

### System for Digitalized Audio Objects Synthesis

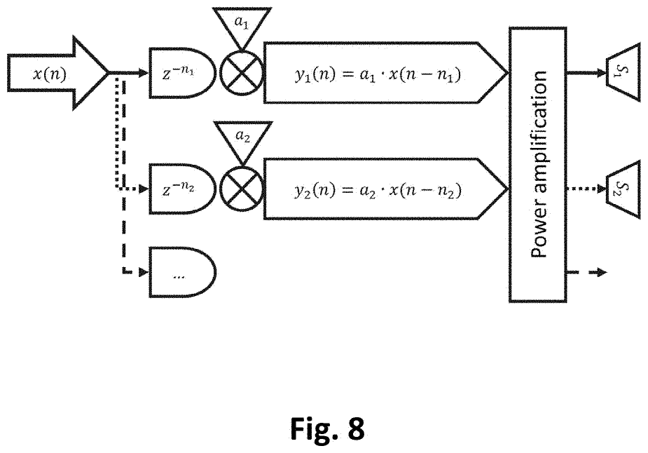

FIG. 8 provides a schematic diagram of a system applying digitalized monopole synthesis algorithm.

The theoretical background of this system is described in more detail in patent application US 2016/0037282 A1 which is herewith incorporated by reference.

The technique which is implemented in the embodiments of US 2016/0037282 A1 is conceptually similar to the Wavefield synthesis, which uses a restricted number of acoustic enclosures to generate a defined sound field. The fundamental basis of the generation principle of the embodiments is, however, specific, since the synthesis does not try to model the sound field exactly but is based on a least square approach.

A target sound field is modelled as at least one target monopole placed at a defined target position. In one embodiment, the target sound field is modelled as one single target monopole. In other embodiments, the target sound field is modelled as multiple target monopoles placed at respective defined target positions. The position of a target monopole may be moving. For example, a target monopole may adapt to the movement of a noise source to be attenuated. If multiple target monopoles are used to represent a target sound field, then the methods of synthesizing the sound of a target monopole based on a set of defined synthesis monopoles, as described below, may be applied for each target monopole independently, and the contributions of the synthesis monopoles obtained for each target monopole may be summed to reconstruct the target sound field.

A source signal x(n) is fed to delay units labelled by z^{-np} and to amplification units aₚ, where p=1, . . . , N is the index of the respective synthesis monopole used for synthesizing the target monopole signal. The delay and amplification units according to this embodiment may apply equation (117) of US 2016/0037282 A1 to compute the resulting signals yₚ(n)=sₚ(n), which are used to synthesize the target monopole signal. The resulting signals sₚ(n) are power amplified and fed to loudspeaker Sₚ.

In this embodiment, the synthesis is thus performed in the form of delayed and amplified components of the source signal x.

According to this embodiment, the delay n, for a synthesis monopole indexed p is corresponding to the propagation time of sound for the Euclidean distance r=Rₚ₀=|rₚ−r₀| between the target monopole r₀ and the generator rₚ.

Further, according to this embodiment, the amplification factor

$${a}_{p} = \frac{{ρ}_{c}}{{R}_{po}}$$

is inversely proportional to the distance r=Rₚ₀.

In alternative embodiments of the system, the modified amplification factor according to equation (118) of US 2016/0037282 A1 can be used.

In yet further alternative embodiments of the system, a mapping factor as described with regard to FIG. 9 of US 2016/0037282 A1 can be used to modify the amplification.

### Audio Input Signal Enhancement

FIG. 9 schematically shows an embodiment of audio input signal enhancement, wherein the audio signal being input to for downmixing, as described in FIG. 2, is an enhanced audio signal.

A spectral decoupling 600 is performed to spectrally decouple the different audio sources (e.g. instruments) of the three-dimensional, 3D, audio signal 200 to obtain a decoupled spectral 601 of the three-dimensional, 3D, audio signal 200. A spectral overlap comparison 602 compares the decoupled spectral 601 of the three-dimensional, 3D, audio signal 200 to obtain an enhanced three-dimensional, 3D, audio signal 603.

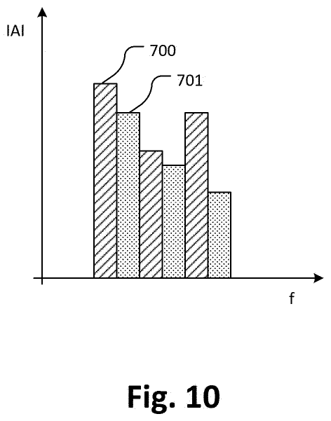

In the embodiment of FIG. 9, the spectral decoupling 600 is performed on the three-dimensional, 3D, audio signal 200 to enhance the three-dimensional, 3D, audio signal 200 by spectrally decoupling the different instruments of the audio signal such that the audio source separation, e.g. BSS, algorithm which is performed on a receiver side (see 204 in FIG. 2) may be performed in an optimized quality. The spectral overlap comparison 602 determines whether there is a spectral overlap. If there is no overlap of e.g. two audio sources in the audio signal, the audio mixture may be simply transmitted to the receiver (see 204 in FIG. 2). If there is a spectral overlap of e.g. two audio sources in the three-dimensional, 3D, audio signal, the spectrally overlapped audio sources may be spectrally weaved together, e.g., with an odd and even Fast Fourier Transform, FFT, bin usage for each audio source, e.g. each instrument (see FIG. 10). If the spectral overlap cannot be avoided, more channels or audio objects may be transmitted to the receiver, such that the quality bandwidth ratio may be dynamically optimized.

Alternatively, if two or more spectrally interwoven instruments are present in the mix, the instruments may be transmitted in a temporal alternating fashion. The receiver may get the information, that both instruments still play simultaneously and then render them in a parallel fashion.

It should be noted that the spectral decoupling 600 and the spectral overlap comparison 602 may minimize artefacts which may occur during decoding, while maintaining a decent quality as a classical stereo mix.

The spectral mixing approach described with regard to FIG. 9 may be used in classical music production. The transmitted audio may be re-mixed in the 3D space using highly compressed binary mixing data. In this manner, the number of channels for multi-channel or object-based audio data transmission is reduced, the quality level of the transmission may be dynamically adjusted and there may be possible compatibility to a normal stereo audio production.

FIG. 10 shows a histogram of two instruments of an audio signal, wherein the two instruments have a spectral overlap. The abscissa displays the frequency and the ordinate the amplitude of the signal of each instrument. One instrument is represented by diagonal lined pattern and the other instrument is represented by doted pattern. Each rectangular 700, 701 represents a frequency bin (frequency domain data points), wherein the frequency bins are intervals between samples in frequency domain. The entire range of signal values is divided into a series of intervals.

If there is a spectral overlap of for example, two audio sources (e.g. instruments) in the audio signal, the spectrally overlapped audio sources may be spectrally weaved together, e.g., with an odd and even Fast Fourier Transform, FFT, bin usage for each audio source, e.g. each instrument.

### Method

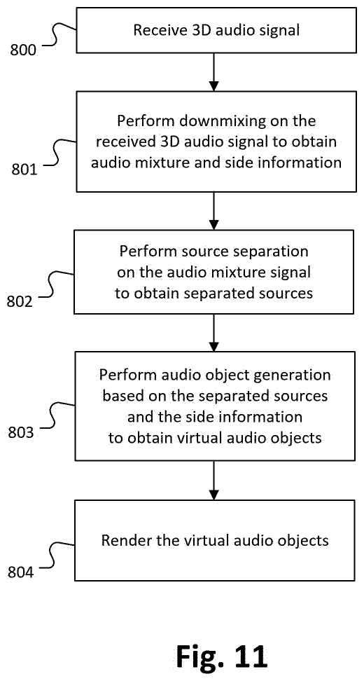

FIG. 11 shows a flow diagram visualizing a method for performing downmixing and remixing/upmixing of an audio signal using audio source separation.

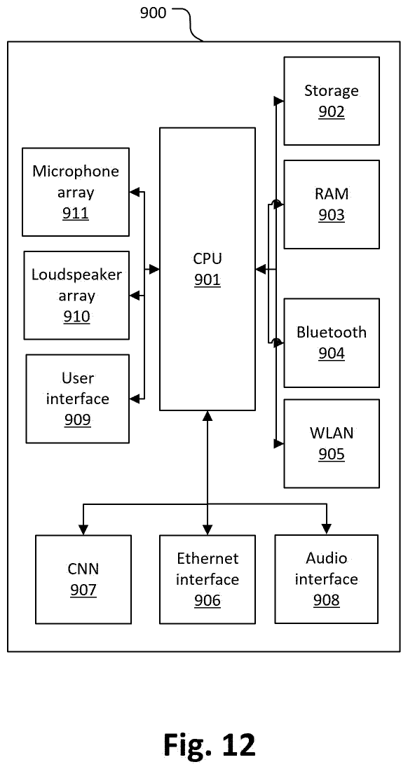

At 800, the electronic system receives a three-dimensional, 3D, audio signal (see 200 in FIGS. 2, 3). At 801, downmixing (see 300 in FIG. 3) is performed on the received 3D audio signal to obtain an audio mixture signal (see 202 in FIGS. 2, 3, 5), e.g., stereo audio signal or monaural audio signal, and side information (see 203 in FIGS. 2, 3, 5, 6) e.g. 3D mixing parameters. At 802, source separation (see 400 in FIG. 5) e.g., blind source separation, is performed on the received audio mixture signal to obtain separated sources (see 401-1, 401-2, 401-3 in FIG. 6). At 803, audio object generation (see 402 in FIG. 5) is performed based on the separated sources (see 401 in FIG. 5) and the side information to obtain virtual audio objects (see 205 in FIGS. 2, 3, 5) e.g., monopoles. At 804, rendering in the 3D space the generated virtual audio objects. For example, the generated virtual audio objects are rendered by means of a loudspeaker system (see 910 in FIG. 12) of an electronic device (see 900 in FIG. 12).

### Implementation

FIG. 12 schematically describes an embodiment of an electronic device that can implement the process of virtual audio object generation based on an audio mixture signal and side information related to the audio mixture signal and the process of rendering the generated virtual audio objects, as described above. The electronic device 900 comprises a CPU 901 as processor. The electronic device 900 further comprises a microphone array 911, a loudspeaker array 910 and a convolutional neural network (CNN) unit 907 that are connected to the processor 901. Processor 901 may for example implement downmixing 300, mixing parameters extraction 301, blind source separation 600 and audio object generation 602 that realize the processes described with regard to FIG. 2, FIG. 3, FIG. 5, FIG. 8 and FIG. 9 in more detail. The CNN unit 907 may for example be an artificial neural network in hardware, e.g., a neural network on GPUs or any other hardware specialized for the purpose of implementing an artificial neural network. Loudspeaker array 910 consists of one or more loudspeakers that are distributed over a predefined space and is configured to render 3D audio. The electronic device 900 further comprises an audio interface 908 that is connected to the processor 901. The audio interface 908 acts as an input interface via which the user is able to input an audio signal, for example an audio interface can be a USB audio interface, or the like. Moreover, the electronic device 900 further comprises a user interface 909 that is connected to the processor 901. This user interface 909 acts as a man-machine interface and enables a dialogue between an administrator and the electronic system. For example, an administrator may make configurations to the system using this user interface 909. The electronic device 900 further comprises an Ethernet interface 906, a Bluetooth interface 904, and a WLAN interface 905. These units 904, 905 and 906 act as I/O interfaces for data communication with external devices. For example, additional loudspeakers, microphones, and video cameras with Ethernet, WLAN or Bluetooth connection may be coupled to the processor 901 via these interfaces 904, 905 and 906.

The electronic system 900 further comprises a data storage 902 and a data memory 903 (here a RAM). The data memory 903 is arranged to temporarily store or cache data or computer instructions for processing by the processor 901. The data storage 902 is arranged as a long-term storage, e.g. for recording sensor data obtained from the microphone array 911. The data storage 902 may also store audio data that represents audio messages, which the public announcement system may transport to people moving in the predefined space.

It should be noted that the description above is only an example configuration. Alternative configurations may be implemented with additional or other sensors, storage devices, interfaces, or the like.

It should be recognized that the embodiments describe methods, e.g., FIG. 11, with an exemplary ordering of method steps. The specific ordering of method steps is, however, given for illustrative purposes only and should not be construed as binding.

It should also be noted that the division of the electronic system of FIG. 12 into units is only made for illustration purposes and that the present disclosure is not limited to any specific division of functions in specific units. For instance, at least parts of the circuitry could be implemented by a respectively programmed processor, field programmable gate array (FPGA), dedicated circuits, and the like.

All units and entities described in this specification and claimed in the appended claims can, if not stated otherwise, be implemented as integrated circuit logic, for example, on a chip, and functionality provided by such units and entities can, if not stated otherwise, be implemented by software.

In so far as the embodiments of the disclosure described above are implemented, at least in part, using software-controlled data processing apparatus, it will be appreciated that a computer program providing such software control and a transmission, storage or other medium by which such a computer program is provided are envisaged as aspects of the present disclosure.

Note that the present technology can also be configured as described below.
(1) An electronic device comprising circuitry configured to
   receive an audio mixture signal (202) and side information (203) related to sources (203-1, 203-2, 203-3) present in the audio mixture signal (202);
   perform audio source separation (400) on the audio mixture (202) to obtain separated sources (401; 401-1, 401-2, 401-3); and
   generate respective virtual audio objects (205) based on the separated sources (401) and the side information (203).
(2) The electronic device of (1), wherein the side information (203) comprises respective rendering information (X, Y, Z) for each of the separated sources (401; 401-1, 401-2, 401-3).
(3) The electronic device of (2), wherein the circuitry is configured to generate a virtual audio object (205) by associating a separated source (401-1, 401-2, 401-3) to its respective rendering information (X, Y, Z).
(4) The electronic device of any one of (1) to (3), wherein the side information (203) is received as binary data.
(5) The electronic device of any one of (1) to (4), wherein the side information (203) is received as inaudible data included in the audio mixture signal (202).
(6) The electronic device of any one of (1) to (5), wherein the side information (203) comprises information indicating that a specific source (203-1, 203-2, 203-3) is present in the audio mixture signal (202).
(7) The electronic device of any one of (1) to (6), wherein the side information (203) comprises information indicating spatial positioning parameters (X, Y, Z) for a specific source (203-1, 203-2, 203-3).
(8) The electronic device of any one of (1) to (7), wherein the side information (203) comprises information indicating a network architecture to be used for source separation (400).
(9) The electronic device of any one of (1) to (8), wherein the side information (203) comprises information indicating a separator model among a plurality of stored separator models to be used for audio source separation (400).
(10) The electronic device of any one of (1) to (9), wherein the circuitry is further configured to render the generated virtual audio object (205) by means of a playback device (206).
(11) The electronic device of any one of (1) to (10), wherein the audio mixture signal (202) is a stereo signal.
(12) The electronic device of any one of (1) to (11), wherein the audio mixture signal (202) is a monaural signal.
(13) An electronic device comprising circuitry configured to
   perform downmixing (300) on a 3D audio signal (200) to obtain an audio mixture signal (202);
   perform mixing parameters extraction (301) on the 3D audio signal (200) to obtain side information (203); and
   transmit the audio mixture signal (202) and the side information (203) related to sources (203-1, 203-2, 203-3) present in the audio mixture signal (202).
(14) The electronic device of (13), wherein the side information (203) comprises rendering information (203-1, 203-2, 203-3) related to the 3D audio signal (200).
(15) The electronic device of (13) or (14), wherein the circuitry is configured to perform spectral decoupling (600) on the 3D audio signal (200) to obtain a decoupled spectral (601) of the 3D audio signal (200).
(16) The electronic device of (15), wherein the circuitry is configured to perform spectral overlap comparison (602) of the decoupled spectral (601) of the 3D audio signal (200) to obtain an enhanced 3D audio signal (200).
(17) A system comprising:
   first electronic device according to claim 13 configured to perform downmixing (300) on a 3D audio signal (200) and to transmit an audio mixture signal (202) and side information (203) to a second electronic device according to claim 1, wherein the second electronic device is configured to generate respective virtual audio objects (205) based on the audio mixture signal (202) and the side information (203) obtained from the first electronic device.
(18) A method comprising:
   receiving an audio mixture signal (202) and side information (203) related to sources (203-1, 203-2, 203-3) present in the audio mixture signal (202);
   performing audio source separation (400) on the audio mixture (202) to obtain separated sources (401); and
   generating respective virtual audio objects (205) based on the separated sources (401) and the side information (203).
(19) A computer program comprising program code causing a computer to perform the method of claim 18, when being carried out on a computer.

1. An electronic device comprising circuitry configured to
receive an audio mixture signal and side information related to sources present in the audio mixture signal;
perform audio source separation on the audio mixture to obtain separated sources; and
generate respective virtual audio objects based on the separated sources and the side information.

2. The electronic device of claim 1, wherein the side information comprises respective rendering information for each of the separated sources.

3. The electronic device of claim 2, wherein the circuitry is configured to generate a virtual audio object by associating a separated source to its respective rendering information.

4. The electronic device of claim 1, wherein the side information is received as binary data.

5. The electronic device of claim 1, wherein the side information is received as inaudible data included in the audio mixture signal.

6. The electronic device of claim 1, wherein the side information comprises information indicating that a specific source is present in the audio mixture signal.

7. The electronic device of claim 1, wherein the side information comprises information indicating spatial positioning parameters for a specific source.

8. The electronic device of claim 1, wherein the side information comprises information indicating a network architecture to be used for source separation.

9. The electronic device of claim 1, wherein the side information comprises information indicating a separator model among a plurality of stored separator models to be used for audio source separation.

10. The electronic device of claim 1, wherein the circuitry is further configured to render the generated virtual audio object by means of a playback device.

11. The electronic device of claim 1, wherein the audio mixture signal is a stereo signal.

12. The electronic device of claim 1, wherein the audio mixture signal is a monaural signal.

13. An electronic device comprising circuitry configured to
perform downmixing on a 3D audio signal to obtain an audio mixture signal;
perform mixing parameters extraction on the 3D audio signal to obtain side information; and
transmit the audio mixture signal and the side information related to sources present in the audio mixture signal.

14. The electronic device of claim 13, wherein the side information comprises rendering information related to the 3D audio signal.

15. The electronic device of claim 13, wherein the circuitry is configured to perform spectral decoupling on the 3D audio signal to obtain a decoupled spectral of the 3D audio signal.

16. The electronic device of claim 15, wherein the circuitry is configured to perform spectral overlap comparison of the decoupled spectral of the 3D audio signal to obtain an enhanced 3D audio signal.

17. A system comprising:
a first electronic device comprising circuitry configured to
perform downmixing on a 3D audio signal to obtain an audio mixture signal;
perform mixing parameters extraction on the 3D audio signal to obtain side information; and
transmit the audio mixture signal and the side information related to sources present in the audio mixture signal; and
a second electronic device comprising circuitry configured to
receive the audio mixture signal and the side information related to sources present in the audio mixture signal;
perform audio source separation on the audio mixture to obtain separated sources; and
generate respective virtual audio objects based on the separated sources and the side information, wherein
the second electronic device is configured to generate respective virtual audio objects based on the audio mixture signal and the side information obtained from the first electronic device.

18. A method comprising:
receiving an audio mixture signal and side information related to sources present in the audio mixture signal;
performing audio source separation on the audio mixture to obtain separated sources; and
generating respective virtual audio objects based on the separated sources and the side information.

19. A non-transitory computer readable medium including a computer program comprising program code causing a computer to perform the method of claim 18, when being carried out on a computer.
